(19) United States
(12) Patent Application Publication
(10) Pub. No.: US 2024/0379700 A1
(43) Pub. Date: Nov. 14, 2024

(54) IMAGE SENSING DEVICE

(71) Applicant: SK hynix Inc., Icheon-si (KR)

(72) Inventor: Jong Hwan SHIN, Icheon-si (KR)

(21) Appl. No.: 18/511,840

(22) Filed: Nov. 16, 2023

(30) Foreign Application Priority Data
May 11, 2023 (KR) 10-2023-0060990

(51) Int. Cl. H01L 27/146

(52) U.S. Cl. CPC H01L 27/14614; H01L 27/1463; H01L 27/14643

(57) ABSTRACT

An image sensing device includes a plurality of unit pixels formed to generate pixel signals corresponding to incident light through photoelectric conversion of the incident light. Each of the unit pixels includes a well tap region configured to apply a bias voltage to a well region of a substrate, a first sub-pixel located at a first side of the well tap region and configured to include a first photoelectric conversion region, a first pixel transistor, a first floating diffusion region, and a first transfer gate, and a second sub-pixel located at a second side of the well tap region that is opposite to the first side of the well tap region and configured to include a second photoelectric conversion region, a second pixel transistor, a second floating diffusion region, and a second transfer gate.

### CROSS-REFERENCE TO RELATED APPLICATION

This patent document claims the priority and benefits of Korean patent application No. 10-2023-0060990, filed on May 11, 2023, which is incorporated by reference in its entirety as part of the disclosure of this patent document.

### TECHNICAL FIELD

The technology and implementations disclosed in this patent document generally relate to an image sensing device.

### BACKGROUND

An image sensor is used in electronic devices to convert optical images into electrical signals. With the recent development of automotive, medical, computer and communication industries, the demand for highly integrated, higher-performance image sensing devices in, for example, smartphones, digital cameras, game consoles, Internet of Things (IoT), robots, surveillance cameras, medical micro-cameras, etc., has been rapidly increasing.

Image sensors may be broadly classified into CCD (Charge Coupled Device) image sensors and CMOS (Complementary Metal Oxide Semiconductor) image sensors. The CMOS image sensing device can be integrated into a single chip, making it easy to miniaturize the sensors for implementation in a product, with the added benefit of consuming lower power consumption. In addition, the CMOS image sensing device can be fabricated using a CMOS fabrication technology, which results in low manufacturing cost. The CMOS image sensing devices have been widely used due to their suitability for implementation in mobile devices.

### SUMMARY

Various embodiments of the disclosed technology relate to an image sensing device capable of improving transfer efficiency of a transfer transistor.

In accordance with an embodiment of the disclosed technology, an image sensing device may include a plurality of unit pixels, each pixel unit configured to generate pixel signals corresponding to incident light through photoelectric conversion of the incident light. Each of the plurality of unit pixels may include a well tap region configured to apply a bias voltage to a well region of a substrate that supports the plurality of unit pixels; a first sub-pixel located at a first side of the well tap region and configured to include a first photoelectric conversion region that converts received light into photocharges, a first floating diffusion region located adjacent to the first photoelectric conversion region to receive and store the photocharges from the first photoelectric conversion region, a first transfer gate coupled between the first floating diffusion region and the first photoelectric conversion region to transfer the photocharges and a first pixel transistor as part of a readout circuit of the first sub-pixel; and a second sub-pixel located at a second side of the well tap region that is opposite to the first side of the well tap region, the second sub-pixel configured to include a second photoelectric conversion region that converts received light into photocharges, a second floating diffusion region located adjacent to the second photoelectric conversion region to receive and store the photocharges from the second photoelectric conversion region, a second transfer gate coupled between the second floating diffusion region and the second photoelectric conversion region to transfer the photocharges, and a second pixel transistor as part of a readout circuit of the second sub-pixel.

In accordance with another embodiment of the disclosed technology, an image sensing device may include a first photoelectric conversion region formed to generate photocharges through photoelectric conversion of incident light; a first transfer gate disposed to vertically overlap the first photoelectric conversion region to transfer the photocharges out of the first photoelectric conversion region; a first floating diffusion region disposed between a central portion of the first photoelectric conversion region and the first transfer gate to receive the photocharges transferred by the first transfer gate from the first photoelectric conversion region; and a first isolation structure formed to surround the first photoelectric conversion region, the first transfer gate, and the first floating diffusion region, the first isolation structure defining a first unit pixel region. The first transfer gate may include a side surface having a first protrusion protruding toward the central portion of the first photoelectric conversion region.

It is to be understood that both the foregoing general description and the following detailed description of the disclosed technology are illustrative and explanatory and are intended to provide further explanation of the disclosure as claimed.

### BRIEF DESCRIPTION OF THE DRAWINGS

The above and other features and beneficial aspects of the disclosed technology will become readily apparent with reference to the following detailed description when considered in conjunction with the accompanying drawings.

FIG. 1 is a block diagram illustrating an example of an image sensing device based on some implementations of the disclosed technology.

FIG. 2 is a plan view illustrating an example structure of a unit pixel group shown in FIG. 1 based on some implementations of the disclosed technology.

FIG. 3 is a plan view illustrating an example structure of any one of unit pixels shown in FIG. 2 based on some implementations of the disclosed technology.

FIG. 4A is a cross-sectional view illustrating an example of the unit pixel taken along the line X1-X1′ shown in FIG. 3 based on some implementations of the disclosed technology.

FIG. 4B is a cross-sectional view illustrating an example of the unit pixel taken along the line X2-X2′ shown in FIG. 3 based on some implementations of the disclosed technology.

FIG. 4C is a cross-sectional view illustrating an example of the unit pixel taken along the line X3-X3′ shown in FIG. 3 based on some implementations of the disclosed technology.

FIG. 5 is a cross-sectional view illustrating an example of the unit pixel taken along the line Y1-Y1′ shown in FIG. 3 based on some implementations of the disclosed technology.

FIGS. 6A and 6B are diagrams illustrating examples of planar structures of transfer gates based on some other implementations of the disclosed technology.

### DETAILED DESCRIPTION

This patent document provides implementations and examples of an image sensing device that may be used to substantially address one or more technical or engineering issues and mitigate limitations or disadvantages encountered in some other image sensing devices. Some implementations of the disclosed technology suggest examples of an image sensing device capable of improving transfer efficiency of a transfer transistor. The disclosed technology provides various implementations of an image sensing device which improves operation characteristics thereof, thereby improving transfer efficiency of the transfer transistor.

Reference will now be made in detail to certain embodiments, examples of which are illustrated in the accompanying drawings. Wherever possible, the same reference numbers will be used throughout the drawings to refer to the same or similar parts. In the following description, a detailed description of related known configurations or functions incorporated herein will be omitted to avoid obscuring the subject matter.

Hereafter, various embodiments will be described with reference to the accompanying drawings. However, it should be understood that the disclosed technology is not limited to specific embodiments, but includes various modifications, equivalents and/or alternatives of the embodiments. The embodiments of the disclosed technology may provide a variety of effects capable of being directly or indirectly recognized through the disclosed technology.

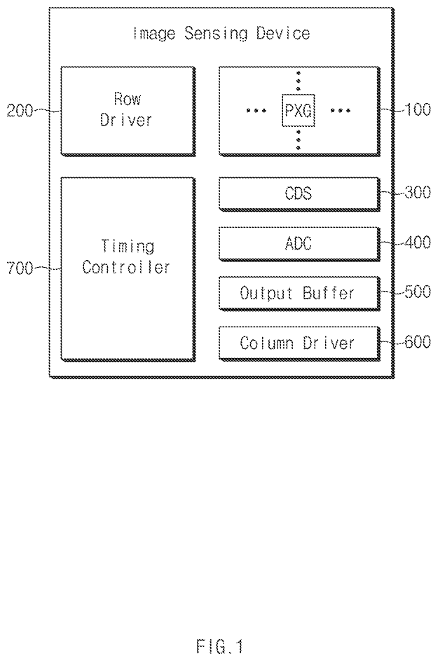

FIG. 1 is a block diagram illustrating an image sensing device based on some implementations of the disclosed technology.

Referring to FIG. 1, the image sensing device may include a pixel array 100, a row driver 200, a correlated double sampler (CDS) 300, an analog-digital converter (ADC) 400, an output buffer 500, a column driver 600 and a timing controller 700. The components of the image sensing device illustrated in FIG. 1 are discussed by way of example only, and this patent document encompasses numerous other changes, substitutions, variations, alterations, and modifications. In this patent document, the word “pixel” can be used to indicate an image sensing pixel that is structured to detect incident light to generate electrical signals carrying images in the incident light, and a phase detection pixel that is structured to generate second electrical signals for calculating a phase difference between the images.

The pixel array 100 may include a plurality of unit pixel groups (PXGs) arranged in a two-dimensional structure. Each unit pixel group (PXG) may include a plurality of unit pixels, each of which converts incident light received from the outside into an electrical signal (i.e., a pixel signal) required to generate an image signal corresponding to a target object to be captured. For example, each unit pixel group (PXG) may include four adjacent unit pixels arranged in a (2×2) matrix structure. The plurality of unit pixels may generate a pixel signal for each unit pixel, or may generate a pixel signal for each pixel group.

Each unit pixel may include a photoelectric conversion region configured to generate photocharges through photoelectric conversion of incident light, and a floating diffusion (FD) region configured to receive and store the photocharges generated in a photoelectric conversion region. In some implementations, each of the plurality of unit pixels may include photoelectric conversion regions arranged to be isolated from each other in a manner that each photoelectric conversion region independently performs photoelectric conversion, and a plurality of floating diffusion (FD) regions arranged in one-to-one correspondence with the photoelectric conversion regions. The floating diffusion (FD) regions included in each unit pixel group (PXG) may be connected to each other through a conductive line.

The pixel array 100 may receive driving signals (for example, a row selection signal, a reset signal, a transmission (or transfer) signal, etc.) from the row driver 200. Upon receiving the driving signal, the unit pixels may be activated to perform the operations corresponding to the row selection signal, the reset signal, and the transfer signal.

The row driver 200 may activate the pixel array 100 to perform certain operations on the unit pixels in the corresponding row based on control signals provided by controller circuitry such as the timing controller 700. In some implementations, the row driver 200 may select one or more pixel groups arranged in one or more rows of the pixel array 100. The row driver 200 may generate a row selection signal to select one or more rows from among the plurality of rows. The row driver 200 may sequentially enable the reset signal and the transfer signal for the unit pixels arranged in the selected row. The pixel signals generated by the unit pixels arranged in the selected row may be output to the correlated double sampler (CDS) 300.

The correlated double sampler (CDS) 300 may remove undesired offset values of the unit pixels using correlated double sampling. In one example, the correlated double sampler (CDS) 300 may remove the undesired offset values of the unit pixels by comparing output voltages of pixel signals (of the unit pixels) obtained before and after photocharges generated by incident light are accumulated in the sensing node (i.e., a floating diffusion (FD) node). As a result, the CDS 300 may obtain a pixel signal generated only by the incident light without causing noise. In some implementations, upon receiving a clock signal from the timing controller 700, the CDS 300 may sequentially sample and hold voltage levels of the reference signal and the pixel signal, which are provided to each of a plurality of column lines from the pixel array 100. That is, the CDS 300 may sample and hold the voltage levels of the reference signal and the pixel signal which correspond to each of the columns of the pixel array 100. In some implementations, the CDS 300 may transfer the reference signal and the pixel signal of each of the columns as a correlate double sampling (CDS) signal to the ADC 400 based on control signals from the timing controller 700.

The ADC 400 is used to convert analog CDS signals received from the CDS 300 into digital signals. In some implementations, the ADC 400 may be implemented as a ramp-compare type ADC. The analog-to-digital converter (ADC) 400 may compare a ramp signal received from the timing controller 700 with the CDS signal received from the CDS 300, and may thus output a comparison signal indicating the result of comparison between the ramp signal and the CDS signal. The analog-to-digital converter (ADC) 400 may count a level transition time of the comparison signal in response to the ramp signal received from the timing controller 700, and may output a count value indicating the counted level transition time to the output buffer 500.

The output buffer 500 may temporarily store column-based image data provided from the ADC 400 based on control signals of the timing controller 700. The image data received from the ADC 400 may be temporarily stored in the output buffer 500 based on control signals of the timing controller 700. The output buffer 500 may provide an interface to compensate for data rate differences or transmission rate differences between the image sensing device and other devices.

The column driver 600 may select a column of the output buffer 500 upon receiving a control signal from the timing controller 700, and sequentially output the image data, which are temporarily stored in the selected column of the output buffer 500. In some implementations, upon receiving an address signal from the timing controller 700, the column driver 600 may generate a column selection signal based on the address signal, may select a column of the output buffer 500 using the column selection signal, and may control the image data received from the selected column of the output buffer 500 to be output as an output signal.

The timing controller 700 may generate signals for controlling operations of the row driver 200, the ADC 400, the output buffer 500 and the column driver 600. The timing controller 700 may provide the row driver 200, the column driver 600, the ADC 400, and the output buffer 500 with a clock signal required for the operations of the respective components of the image sensing device, a control signal for timing control, and address signals for selecting a row or column. In some implementations, the timing controller 700 may include a logic control circuit, a phase lock loop (PLL) circuit, a timing control circuit, a communication interface circuit and others.

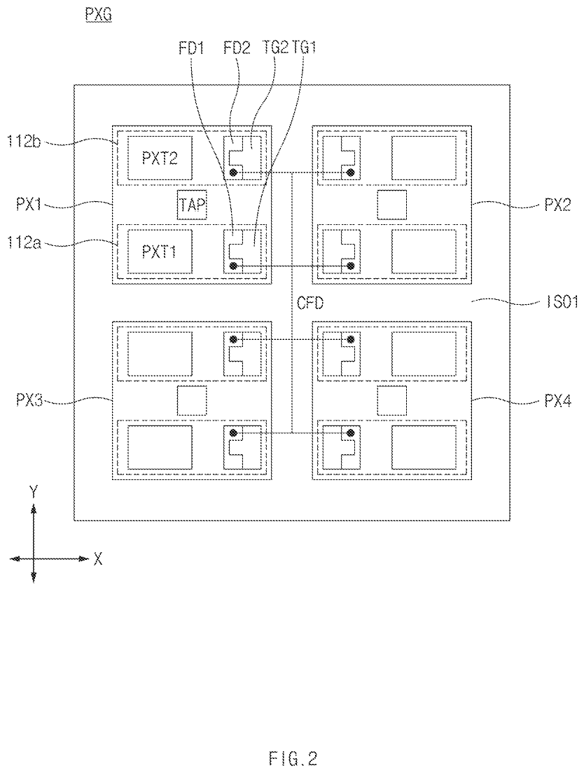

FIG. 2 is a plan view illustrating an example structure of a unit pixel group (PXG) within the pixel array 100 formed by a plurality of unit pixel groups (PXGs) shown in FIG. 1 based on some implementations of the disclosed technology.

Referring to FIG. 2, each unit pixel group (PXG) may include a group of adjacent unit pixels, e.g., four unit pixels PX1 to PX4 as illustrated in this particular implementation example in FIG. 2. The unit pixels PX1 to PX4 may be disposed adjacent to each other in a first direction (e.g., an X-axis direction) and in a second direction (e.g., a Y-axis direction) perpendicular to the first direction. In this particular example in FIG. 2, each unit pixel group (PXG) may include unit pixels PX1 to PX4 arranged in a (2×2) matrix structure including two rows and two columns.

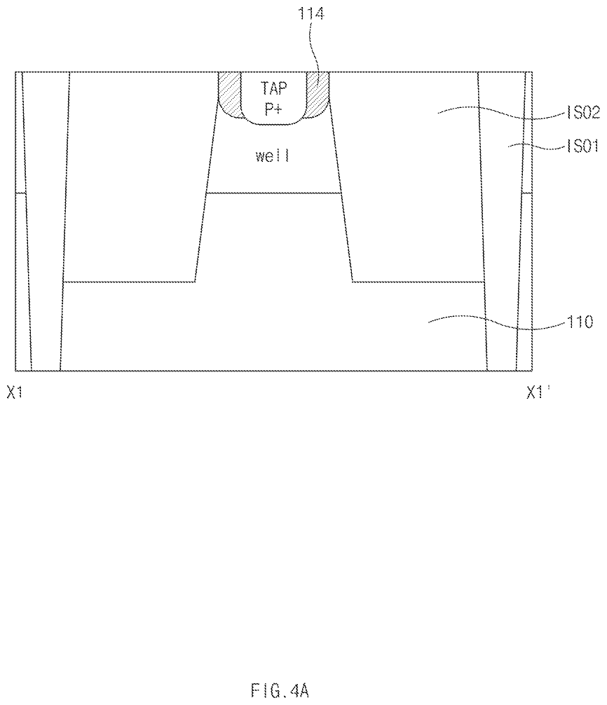

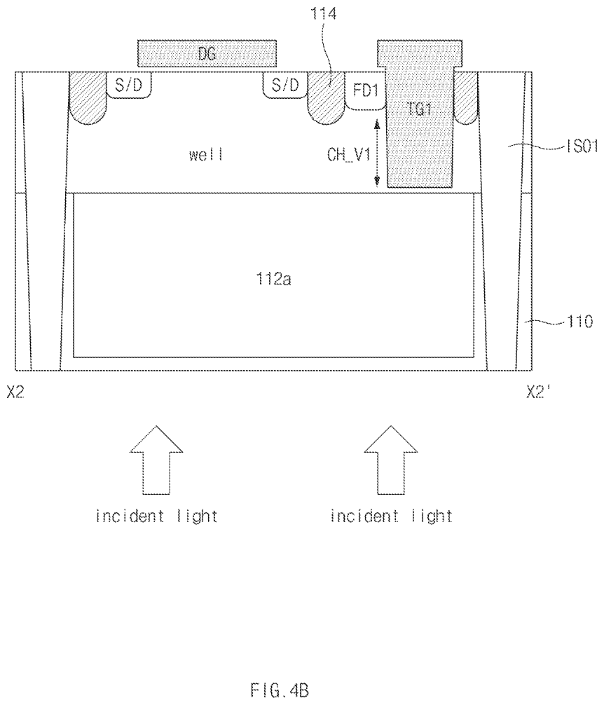

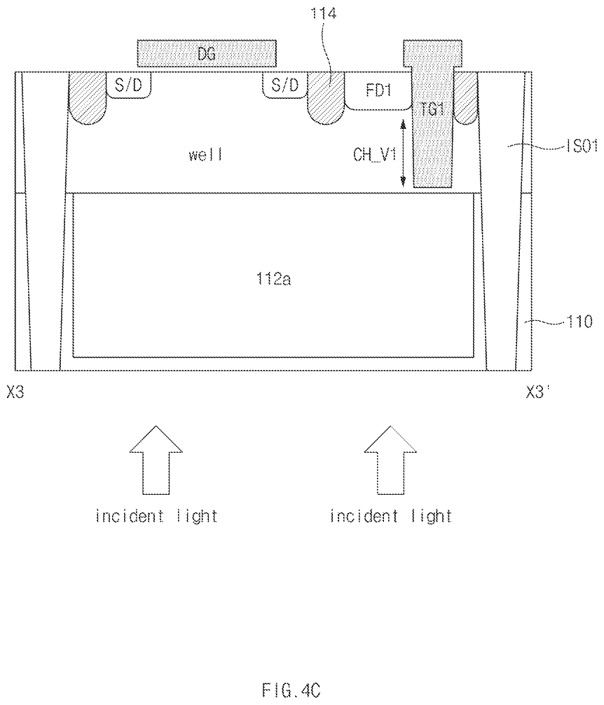

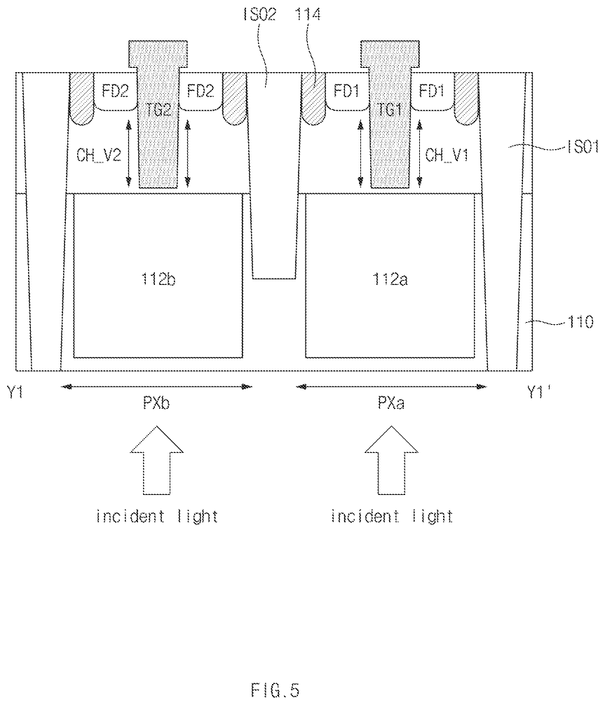

In some implementations, the unit pixels PX1 to PX4 may be included as fully isolated pixels that are physically and completely isolated from each other by a pixel isolation structure ISO1. For example, any two of the unit pixels PX1 to PX4 that are adjacent to each other may not physically share a circuit component, such as photoelectric conversion regions (112a, 112b), floating diffusion (FD) regions (FD1, FD2), pixel transistors (PXT1, PXT2), and a well tap region TAP. Thus, such an isolated single unit pixel each includes its own designated photoelectric conversion region, floating diffusion (FD) region, or one or more transistors which are not formed across two unit pixels adjacent to each other. The unit pixels PX1 to PX4 may be formed in a Back Side Illumination (BSI) structure in which CMOS sensor circuit elements for unit pixels are formed on a front side of the semiconductor substrate while the light receiving surface of the CMOS sensor is on the back side of the semiconductor substrate to receive light that passes through the substrate to reach the CMOS sensor circuit elements of unit pixels where the light transmitted through the substrate is converted into pixel signals as illustrated in the example show in FIGS. 4A to 4C and 5.

In some implementations of the above isolated unit pixels, a sensor device may implement a pixel isolation structure ISO1 to physically separate adjacent unit pixels PX1 to PX4 within each PXG. The pixel isolation structure ISO1 may include, for example, a trench-type isolation structure formed such that an insulation material is buried in a trench between different adjacent unit pixels PX1 to PX4 that may be formed by etching the substrate. In some implementations, the trench-type isolation structure may include a deep trench isolation (DTI) structure or a structure in which a DTI structure and a shallow trench isolation (STI) structure are combined with each other.

An electrical connection between circuit elements belonging to different unit pixels within a PXG may be made through conductive lines (e.g., metal lines) formed over the substrate that supports the unit pixels and the PXGs.

In the unit pixel group PXG, the unit pixels PX1 to PX4 may be identical in structure to each other, and the unit pixels located adjacent to each other in a first direction and a second direction may be arranged symmetrical to each other. In one example of suitable implementations, each of the unit pixels PX1 to PX4 may include a 2-photodiode (2PD) structure including two photoelectric conversion regions (112a, 112b) for receiving light and converting received light into photocharges and two floating diffusion regions (FD1, FD2) are provided to receive the generated photocharges from the two photoelectric conversion regions (112a, 112b), respectively. In addition, two transfer gates (TG1, TG2) and two pixel transistors (PXT1, PXT2) are provided as readout circuits for the two photoelectric conversion regions (112a, 112b), respectively. Furthermore, one common well tap region (TAP) is provided adjacent to the two photoelectric conversion regions (112a, 112b) to provide a common bias voltage.

Each of the pixel transistors (PXT1, PXT2) may be used as part of the readout circuits respectively for the two photoelectric conversion regions (112a, 112b) and thus may be any one of a source follower transistor, a selection transistor, a reset transistor, a conversion gain transistor, or a dummy transistor. For example, in each of the unit pixels PX1 to PX3, the first pixel transistors PXT1 may be used as source follower transistors, and the second pixel transistors PXT2 may be used as selection transistors. In the unit pixel PX4, the first pixel transistor PXT1 may be used as a reset transistor, and the second pixel transistor PXT2 may be used as a dummy transistor or a conversion gain transistor for adjusting capacitance of a common floating diffusion node (CFD).

In each of the unit pixels PX1 to PX4, the pixel transistors (PXT1, PXT2), the transfer gates (TG1, TG2), and the floating diffusion regions (FD1, FD2) may vertically overlap the corresponding photoelectric conversion regions (112a, 1120b). For example, the first pixel transistor PXT1, the first transfer gate TG1, and the first floating diffusion region FD1 may vertically overlap the first photoelectric conversion region 112a. In addition, the second pixel transistor PXT2, the second transfer gate TG2, and the second floating diffusion region FD2 may vertically overlap the second photoelectric conversion region 112b.

In each of the unit pixels PX1 to PX4, the well tap region TAP for applying a bias voltage to a well region in the substrate may be located at the center of the corresponding unit pixel. As such, since the well tap region TAP is located at the center of each unit pixel, a well potential within each unit pixel can be more uniform.

In each of the unit pixels PX1 to PX4, the floating diffusion regions (FD1, FD2) may be disposed between the corresponding pixel transistors (PXT1, PXT2) and the transfer gates (TG1, TG2). In more detail, the floating diffusion region FD1 may be disposed between the pixel transistor PXT1 and the transfer gate TG1, and the floating diffusion region FD2 may be disposed between the pixel transistor PXT2 and the transfer gate TG2. In each pixel group PXG, eight floating diffusion regions (FD1, FD2) may be electrically connected in common through a conductive line to form a common floating diffusion node CFD. The common floating diffusion node CFD may be electrically connected to gates of pixel transistors through a conductive line, each of the pixel transistors being used as a source follower transistor.

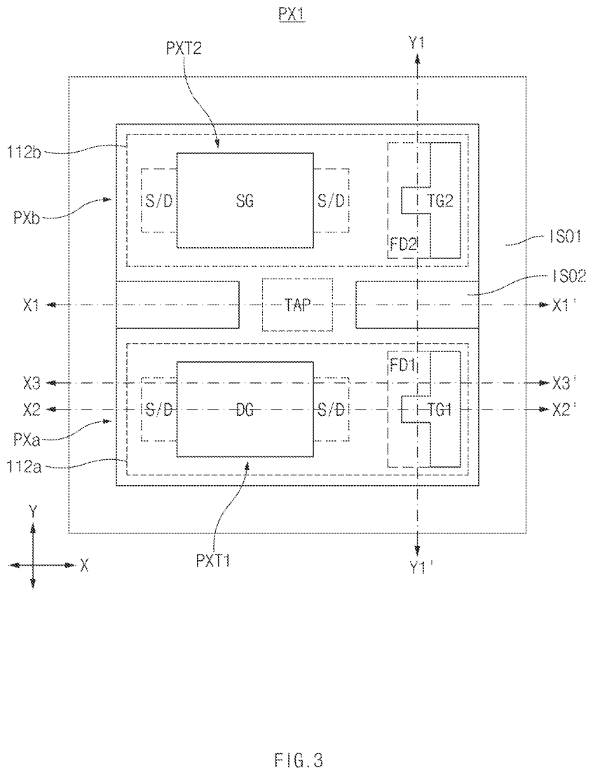

FIG. 3 is a plan view illustrating an example structure of any one of the unit pixels shown in FIG. 2 based on some implementations of the disclosed technology.

The unit pixels PX1 to PX4 may be identical in structure to each other. The following description will be given below with reference to only one unit pixel PX1 among the unit pixels (PX1˜PX4) within a PXG but the same description can be applied to remaining pixels.

Referring to FIG. 3, the unit pixel PX1 may be a fully isolated pixel. The unit pixel PX1 serving as the fully isolated pixel may be physically isolated from other adjacent unit pixels (PX2˜PX4) belonging to the pixel group PXG and other unit pixels (not shown) belonging to other adjacent pixel groups by a pixel isolation structure (ISO1). The pixel isolation structure (ISO1) may include a trench-type isolation structure. In some implementations, the trench-type isolation structure may be formed by etching the substrate to form a trench and depositing an insulation material in the trench. For example, the pixel isolation structure (ISO1) may include a deep trench isolation (DTI) structure.

The unit pixel PX1 may include a first sub-pixel (PXa), a second sub-pixel (PXb), and a well tap region (TAP).

The first sub-pixel (PXa) may be located at one side of the well tap region TAP in a second direction within the unit pixel PX1. The first sub-pixel (PXa) may include a first photoelectric conversion region 112a, a first floating diffusion region FD1, a first transfer gate TG1, and a first pixel transistor PXT1. The first floating diffusion region FD1, the first transfer gate TG1, and the first pixel transistor PXT1 may vertically overlap the first photoelectric conversion region 112a.

When viewed in a plan view, the first photoelectric conversion region 112a may be formed to have the same shape as the first sub-pixel (PXa) such that the length in the first direction is longer than the length in the second direction. The first floating diffusion region FD1, the first transfer gate TG1, and the first pixel transistor PXT1 may be arranged in a line along the first direction over the first photoelectric conversion region 112a. In this case, the first floating diffusion region FD1 may be disposed between the first pixel transistor PXT1 and the first transfer gate TG1. In addition, the first floating diffusion region FD1 may be disposed between the first transfer gate TG1 and the center of the first photoelectric conversion region 112a when viewed in a plan view. Thus, the first floating diffusion region FD1 and the first transfer gate TG1 may be disposed on one side of the center of the first photoelectric conversion region 112a. In this case, the center of the first photoelectric conversion region 112a may refer to the center of a top surface of the first photoelectric conversion region 112a.

The first photoelectric conversion region 112a may generate photocharges through photoelectric conversion of incident light. The first transfer gate TG1 may transmit the photocharges generated by the first photoelectric conversion region 112a to the first floating diffusion region FD1 based on a transfer signal.

The first pixel transistor PXT1 may be disposed to overlap the center of the first photoelectric conversion region 112a, and the first transfer gate TG1 may be disposed to overlap the end portion of the first photoelectric conversion region 112a (e.g., a right end portion in FIG. 3) at one side of the first pixel transistor PXT1. In this case, the first transfer gate TG1 may have side surfaces, a first side surface and a second side surface opposite to the first side surface, and the first side surface that is adjacent to the first pixel transistor PXT1 includes a protrusion. The protrusion is located at a central portion of the first side surface and protrudes toward the first pixel transistor PXT1. Thus, the first transfer gate TG1 may include a protrusion protruding toward the center of the first photoelectric conversion region 112a when viewed in a plan view. In general, a region having the largest capacitance within each photoelectric conversion region is a central region of the photoelectric conversion region. Therefore, the first transfer gate TG1 may be disposed to overlap the end of the first photoelectric conversion region 112a, but a portion (e.g., a central portion) of the first transfer gate TG1 may protrude toward the center of the first photoelectric conversion region 112a so as to be located close to the center of the first photoelectric conversion region 112a, resulting in increased transfer efficiency of the first transfer gate TG1.

The first floating diffusion region FD1 may be located at a protruding side of the first transfer gate TG1. Thus, when viewed in a plan view, the first floating diffusion region FD1 may be disposed between the first transfer gate TG1 and the center of the first photoelectric conversion region 112a, so that the first floating diffusion region FD1 may be formed to surround the protrusion of the first transfer gate TG1. As a result, a contact area between the first transfer gate TG1 and the first floating diffusion region FD1 may increase in size, thereby further increasing the transfer efficiency of the first transfer gate TG1. The first floating diffusion region FD1 may include N-type impurities (N+).

The first pixel transistor PXT1 may be spaced apart from the first floating diffusion region FD1 by a predetermined distance in the first direction, and may include a gate (DG) and junction regions (S/D). The first pixel transistor PXT1 may be used as a source follower transistor or a selection transistor.

The second sub-pixel PXb may be located at the other side of the well tap region TAP in the second direction within the unit pixel PX1. For example, the first sub-pixel PXa and the second sub-pixel PXb may be located symmetrical to each other in the second direction with respect to the well tap region TAP. The second sub-pixel PXb may include a second photoelectric conversion region 112b, a second floating diffusion region FD2, a second transfer gate TG2, and a second pixel transistor PXT2. The second floating diffusion region FD2, the second transfer gate TG2, and the second pixel transistor PXT2 may vertically overlap the second photoelectric conversion region 112b.

The second photoelectric conversion region 112b, the second floating diffusion region FD2, the second transfer gate TG2, and the second pixel transistor PXT2 of the second sub-pixel PXb may be substantially identical in structure and size to the first photoelectric conversion region 112a, the first floating diffusion region FD1, the first transfer gate TG1, and the first pixel transistor PXT1 of the first sub-pixel PXa. Therefore, a description of the arrangement structure of the second photoelectric conversion region 112b, the second floating diffusion region FD2, the second transfer gate TG2, and the second pixel transistor PXT2 will herein be omitted for brevity.

The second photoelectric conversion region 112b may be physically isolated from the first photoelectric conversion region 112a so as to perform photoelectric conversion independently. The photocharges generated by the second photoelectric conversion region 112b may be transferred to the second floating diffusion region FD2 by the second transfer gate TG2. The second pixel transistor PXT2 may be used as a selection transistor or a source follower transistor. For example, when the first pixel transistor PXT1 is used as a source follower transistor, the second pixel transistor PXT2 can be used as a selection transistor.

A plurality of sub-pixel isolation structures (ISO2) may be formed between the first sub-pixel PXa and the second sub-pixel PXb. The sub-pixel isolation structures (ISO2) may be located at both sides of the well tap region TAP in the first direction. Each of the sub-pixel isolation structures (ISO2) may include a trench-type isolation structure. In some implementations, the trench-type isolation structure may be formed by etching the substrate to form a trench and depositing an insulation material in the trench. Each of the sub-pixel isolation structures (ISO2) may include a DTI or STI structure formed to have a depth smaller than that of the pixel isolation structure ISO1.

The well tap region TAP may be used to apply a bias voltage to a well region of the substrate, and may include a high-concentration P-type impurity (P⁺) region. The well tap region TAP may be located at the center of the unit pixel PX1. For example, the well tap region TAP may be disposed in a region between the sub-pixel isolation structures (ISO2) at a position between the first sub-pixel PXa and the second sub-pixel PXb. As such, since the well tap region TAP is located at the center of the unit pixel PX1, the well potential within the unit pixel PX1 can be uniform.

In the unit pixel PX1, the pixel transistors (PXT1, PXT2), the floating diffusion regions (FD1, FD2), and the well tap region TAP may be electrically isolated from each other by a junction isolation structure including high-concentration impurities (e.g., P-type impurities). Alternatively, the pixel transistors (PXT1, PXT2), the floating diffusion regions (FD1, FD2), and the well tap region TAP may be isolated from each other by the STI structure.

Although FIG. 3 shows the example case in which the first sub-pixel PXa and the second sub-pixel PXb are spaced apart from each other while being symmetrical to each other in the second direction within the unit pixel PX1, other implementations are also possible. For example, in some implementations, the first sub-pixel PXa and the second sub-pixel PXb can be spaced apart from each other while being symmetrical to each other in the first direction within the unit pixel PX1.

FIGS. 4A to 4C and 5 shows one implementation example of a PGX in the Back Side Illumination (BSI) structure for the pixel example in FIG. 3. FIG. 4A is a cross-sectional view illustrating an example of the unit pixel taken along the line X1-X1′ shown in FIG. 3. FIG. 4B is a cross-sectional view illustrating an example of the unit pixel taken along the line X2-X2′ shown in FIG. 3. FIG. 4C is a cross-sectional view illustrating an example of the unit pixel taken along the line X3-X3′ shown in FIG. 3. FIG. 5 is a cross-sectional view illustrating an example of the unit pixel taken along the line Y1-Y1′ shown in FIG. 3.

Referring to FIGS. 4A to 4C and 5, the substrate 110 may include a first surface and a second surface facing or opposite to the first surface, and the unit pixel PX1 may be physically isolated from neighboring unit pixels by the pixel isolation structure ISO1. The pixel isolation structure ISO1 may include a DTI structure, and may be formed to pass through the substrate 110. The unit pixel PX1 may include a Back Side Illumination (BSI) structure in which drive elements (PXT1, PXT2, TG1, TG2) are formed at an opposite side of a surface (e.g., a first surface) upon which light is incident. The pixel isolation structure ISO1 may include a Front Deep Trench Isolation (FDTI) structure that is formed by forming a trench that is etched from the second surface toward the first surface and depositing an insulation material in the trench.

In the unit pixel PX1, the photoelectric conversion regions (112a, 112b) of the sub-pixels (PXa, PXb) may be physically isolated from each other by the sub-pixel isolation structures (ISO2). Each of the sub-pixel isolation structures (ISO2) may include a DTI or STI structure formed to have a depth smaller than that of the pixel isolation structure ISO1. The sub-pixel isolation structure ISO2 may be formed not to penetrate the substrate.

The first photoelectric conversion region 112a may be formed in a lower region of the substrate 110 within the first sub-pixel (PXa) region, and the second photoelectric conversion region 112b may be formed in a lower region of the substrate 110 within the second sub-pixel (PXb) region. In this case, in order to increase light reception efficiency, the photoelectric conversion regions (112a, 112b) may be formed as wide as possible in the lower region of the substrate 110 within the corresponding sub-pixels (PXa, PXb). In more detail, the photoelectric conversion region 112a may be formed as wide as possible in the lower region of the substrate 110 within the sub-pixel (PXa), and the photoelectric conversion region 112b may be formed as wide as possible in the lower region of the substrate 110 within the sub-pixel (PXb). For example, the first photoelectric conversion region 112a may be formed in the lower region of the substrate 110 to vertically overlap the first floating diffusion region FD1, the first transfer gate TG1, and the first pixel transistor PXT1. The second photoelectric conversion region 112b may be formed in the lower region of the substrate 110 to vertically overlap the second floating diffusion region FD2, the second transfer gate TG2, and the second pixel transistor PXT2. Each of the photoelectric conversion regions (112a, 112b) may include an N-type impurity region.

The transfer gates TG1 may form a vertical channel (CH_V1) between the photoelectric conversion region 112a and the floating diffusion region FD1 based on the transmission signal so as to transmit photocharges generated by the photoelectric conversion region 112a to the floating diffusion region FD1. The transfer gates TG2 may form a vertical channel (CH_V2) between the photoelectric conversion region 112b and the floating diffusion region FD2 based on the transmission signal so as to transmit photocharges generated by the photoelectric conversion region 112b to the floating diffusion region FD2. For example, the first transfer gate TG1 may include a recessed gate that vertically connects the first photoelectric conversion region 112a to the first floating diffusion region FD1 through the vertical channel (CH_V1). The second transfer gate TG2 may include a recessed gate that vertically connects the second photoelectric conversion region 112b to the second floating diffusion region FD2 through the vertical channel (CH_V2).

A gate insulation layer (not shown) may be formed between the transfer gates (TG1, TG2) and the floating diffusion regions (FD1, FD2). In more detail, a gate insulation layer may be formed between the transfer gate TG1 and the floating diffusion region FD1, and may also be formed between the transfer gate TG2 and the floating diffusion region FD2. For convenience of description, each of the transfer gates (TG1, TG2) may be defined to include a gate insulation layer.

In the unit pixel PX1, the pixel transistors (PXT1, PXT2), the floating diffusion regions (FD1, FD2), and the well tap region TAP may be electrically isolated from each other by a device isolation structure 114. The device isolation structure 114 may include a junction isolation structure that is formed by implanting impurities into an upper portion of the substrate 110. For example, the device isolation structure 114 may include an impurity region that contacts a top surface of the substrate 110 and is implanted with P-type impurities to a predetermined depth from the top surface of the substrate 110.

When a trench structure is present in the substrate 110 of the unit pixel having the fully isolated pixel structure in which the photoelectric conversion regions (112a, 112b) are formed in the lower region of the substrate 110 and photocharges generated by the photoelectric conversion regions (112a, 112b) are transmitted to the floating diffusion regions (FD1, FD2) using the recessed transfer gates (TG1, TG2), the trench structure may cause a dark current and a hot pixel.

In the implementations of the disclosed technology, to avoid or reduce of an occurrence of dark current and hot pixel, the junction-type isolation structure instead of a trench-type isolation structure is configured to isolate the elements (PXT1, PXT2, FD1, FD2, TAP) within the unit pixel PX1. The junction-type isolation structure may be formed by implanting impurities into the substrate 110, while the trench-type isolation structure is formed by etching the substrate 110. By configuring the junction-type isolation structure instead of the trench-type isolation structure, the occurrence of dark current and hot pixels can be minimized.

In some implementations, the transfer gate TG1 may be located at one end of the sub-pixel (PXa) to form a space in which the pixel transistor PXT1 is to be formed, such that a portion (e.g., a central portion) of the transfer gate TG1 is formed to protrude toward the central portion of the photoelectric conversion region 112a. In addition, the transfer gate TG2 may be located at one end of the sub-pixel (PXb) to form a space in which the pixel transistor PXT2 is to be formed, such that a portion (e.g., a central portion) of the transfer gate TG2 is formed to protrude toward the central portion of the photoelectric conversion region 112b. As such, a portion of the transfer gate TG1 may be located close to the central portion having high capacitance within the photoelectric conversion region 112a, and a portion of the transfer gate TG2 may be located close to the central portion having high capacitance within the photoelectric conversion region 112b, so that transfer efficiency of each of the transfer gates TG1 and TG2 can be increased. In addition, since the floating diffusion regions (FD1, FD2) are formed to surround the protrusions of the transfer gates (TG1, TG2), a contact area between the floating diffusion regions (FD1, FD2) and the transfer gates (TG1, TG2) may increase in size, such that the area of each of the vertical channels (CH_V1, CH_V2) can be expanded. As a result, transfer efficiency of each of the transfer gates (TG1, TG2) can be further increased.

The pixel transistors (PXT1, PXT2) may be electrically isolated from the floating diffusion regions (FD1, FD2) by the device isolation structure 114. Each of the gates (DG, SG) of the pixel transistors (PXT1, PXT2) may be formed as a planar gate type on the second surface of the substrate 110.

The well tap region TAP may be used as a region for applying a bias voltage to the well region of the substrate 110, and may include an impurity region in which P-type impurities (P⁺) having higher concentration than the device isolation structure 114 and the well region are implanted. The well tap region TAP may be disposed between the sub-pixel isolation structures (ISO2) at the center of the unit pixel PX1.

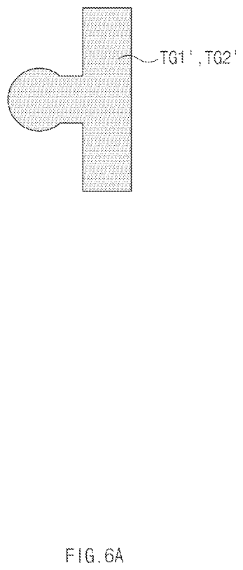

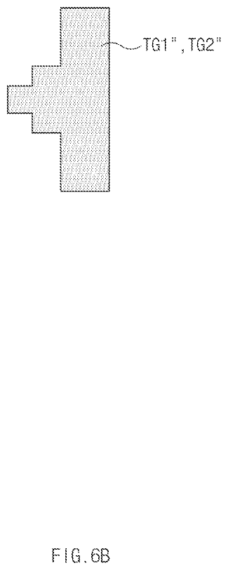

FIGS. 6A and 6B are diagrams illustrating examples of planar structures of transfer gates based on some other implementations of the disclosed technology.

Referring to FIG. 6A, the protrusion of each of the transfer gates TG1′ and TG2′ may be rounded in a bulb shape. As a result, the contact area between the transfer gates (TG1′, TG2′) and the floating diffusion regions (FD1, FD2) may increase in size, as compared to the contact area between the transfer gates (TG1, TG2) and the floating diffusion regions (FD1, FD2) as shown in FIG. 3. With the increase of the contact area between the transfer gates (TG1′, TG2′) and the floating diffusion regions (FD1, FD2), the area of each of the vertical channels (CH_V1, CH_V2) can be further expanded.

Referring to FIG. 6B, the protrusion of each of the transfer gates (TG1″, TG2″) may be formed to protrude in a multi-stage structure. For example, the transfer gates (TG1″, TG2″) may have a first protrusion protruding from the side surface and a second protrusion further protruding from the first protrusion. In this case, the contact area between the transfer gates (TG1″, TG2″) and the floating diffusion regions (FD1, FD2) may increase in size, as compared to the contact area between the floating diffusion regions (FD1, FD2) and the transfer gates (TG1, TG2) as shown in FIG. 3. With the increase of the contact area between the transfer gates (TG1′, TG2′) and the floating diffusion regions (FD1, FD2), the area of each of the vertical channels (CH_V1, CH_V2) can be further expanded.

As is apparent from the above description, the image sensing device based on some implementations of the disclosed technology can improve operation characteristics thereof. In particular, the image sensing device can improve transfer efficiency of the transfer transistor.

The embodiments of the disclosed technology may provide a variety of effects capable of being directly or indirectly recognized through the above-mentioned patent document.

Although a number of illustrative embodiments have been described, it should be understood that various modifications or enhancements of the disclosed embodiments and other embodiments can be devised based on what is described and/or illustrated in this patent document.

What is claimed is:

1. An image sensing device comprising:
a plurality of unit pixels, each unit pixel configured to generate pixel signals corresponding to incident light through photoelectric conversion of the incident light,
wherein each of the plurality of unit pixels includes:
a well tap region configured to apply a bias voltage to a well region of a substrate that supports the plurality of unit pixels;
a first sub-pixel located at a first side of the well tap region and configured to include a first photoelectric conversion region that converts received light into photocharges, a first floating diffusion region located adjacent to the first photoelectric conversion region to receive and store the photocharges from the first photoelectric conversion region, a first transfer gate coupled between the first floating diffusion region and the first photoelectric conversion region to transfer the photocharges and a first pixel transistor as part of a readout circuit of the first sub-pixel; and
a second sub-pixel located at a second side of the well tap region that is opposite to the first side of the well tap region, the second sub-pixel configured to include a second photoelectric conversion region that converts received light into photocharges, a second floating diffusion region located adjacent to the second photoelectric conversion region to receive and store the photocharges from the second photoelectric conversion region, a second transfer gate coupled between the second floating diffusion region and the second photoelectric conversion region to transfer the photocharges, and a second pixel transistor as part of a readout circuit of the second sub-pixel.

2. The image sensing device according to claim 1, wherein:
the well tap region is located at a central portion of the unit pixel.

3. The image sensing device according to claim 1, wherein:
the first pixel transistor, the first floating diffusion region, and the first transfer gate vertically overlap the first photoelectric conversion region.

4. The image sensing device according to claim 3, wherein:
the first pixel transistor is disposed to overlap a central portion of the first photoelectric conversion region; and
the first transfer gate is disposed to overlap an end portion of the first photoelectric conversion region at one side of the first pixel transistor.

5. The image sensing device according to claim 1, wherein:
the first pixel transistor, the first floating diffusion region, and the first transfer gate are arranged in a line along a first direction; and
the first floating diffusion region is disposed between the first pixel transistor and the first transfer gate.

6. The image sensing device according to claim 5, wherein the first transfer gate includes a first side surface and a second side surface opposite to the first side surface, and the first side surface adjacent to the first pixel transistor has a protrusion protruding toward the first pixel transistor.

7. The image sensing device according to claim 6, wherein:
the first floating diffusion region is formed to surround the protrusion.

8. The image sensing device according to claim 6, wherein:
the protrusion protrudes in a bulb shape or protrudes in a multi-stage structure having an additional protrusion protruding from the protrusion.

9. The image sensing device according to claim 1, wherein the first transfer gate includes: a protrusion vertically overlapping the first photoelectric conversion region at one side of the first sub-pixel, and the protrusion disposed at one side surface of the first transfer gate protrudes toward a central portion of the first photoelectric conversion region.

10. The image sensing device according to claim 9, wherein:
the protrusion has a round shape or protrudes in a multi-stage structure having an additional protrusion protruding from the protrusion.

11. The image sensing device according to claim 1, wherein:
the first sub-pixel and the second sub-pixel are symmetrical to each other with respect to the well tap region.

12. The image sensing device according to claim 1, wherein the unit pixel further includes:
a plurality of sub-pixel isolation structures disposed at both sides of the well tap region at a position between the first sub-pixel and the second sub-pixel.

13. An image sensing device comprising:
a first photoelectric conversion region formed to generate photocharges through photoelectric conversion of incident light;
a first transfer gate disposed to vertically overlap the first photoelectric conversion region to transfer the photocharges out of the first photoelectric conversion region;
a first floating diffusion region disposed between a central portion of the first photoelectric conversion region and the first transfer gate to receive the photocharges transferred by the first transfer gate from the first photoelectric conversion region; and
a first isolation structure formed to surround the first photoelectric conversion region, the first transfer gate, and the first floating diffusion region, the first isolation structure defining a first unit pixel region,
wherein the first transfer gate includes a side surface having a first protrusion protruding toward the central portion of the first photoelectric conversion region.

14. The image sensing device according to claim 13, wherein:
the first floating diffusion region is formed to surround the first protrusion.

15. The image sensing device according to claim 13, wherein:
the first protrusion protrudes in a bulb shape or protrudes in a multi-stage structure having an additional protrusion protruding from the first protrusion.

16. The image sensing device according to claim 13, further comprising:
a second photoelectric conversion region disposed in the first unit pixel region and arranged symmetrical to the first photoelectric conversion region, the second photoelectric conversion region configured to generate photocharges through photoelectric conversion of incident light;
a second transfer gate disposed to vertically overlap the second photoelectric conversion region and having a side surface with a second protrusion protruding toward a central portion of the second photoelectric conversion region; and
a second floating diffusion region disposed between a central portion of the second photoelectric conversion region and the second transfer gate and surrounding the second protrusion.

17. The image sensing device according to claim 16, further comprising:
a plurality of second isolation structures disposed between the first photoelectric conversion region and the second photoelectric conversion region in the first unit pixel region; and
a well tap region disposed between two of the plurality of the second isolation structures.

18. The image sensing device according to claim 16, wherein:
the second protrusion protrudes in a bulb shape or protrudes in a multi-stage structure having an additional protrusion protruding from the second protrusion.

19. The image sensing device according to claim 13, further comprising:
a first pixel transistor disposed to vertically overlap the central portion of the first photoelectric conversion region.

20. The image sensing device according to claim 19, wherein:
the first transfer gate is disposed to overlap an end portion of the first photoelectric conversion region at one side of the first pixel transistor.
